(19) United States
(12) Patent Application Publication
(10) Pub. No.: US 2015/0147839 A1
(43) Pub. Date: May 28, 2015

(54) METHOD FOR MANUFACTURING A SEMICONDUCTOR DEVICE

(71) Applicant: Infineon Technologies Dresden GmbH, Dresden (DE)

(72) Inventors: Alessia Scire, Dresden (DE); Alfred Vater, Dresden (DE); Mirko Vogt, Dresden (DE); Momtchil Stavrev, Dresden (DE); Tarja Hauck, Dresden (DE); Bee Kim Hong, Dresden (DE); Heiko Estel, Dresden (DE)

(73) Assignee: Infineon Technologies Dresden GmbH, Dresden (DE)

(21) Appl. No.: 14/089,805

(22) Filed: Nov. 26, 2013

(51) Int. Cl. H01L 21/306; H01L 51/00; H01L 21/3065

(52) U.S. Cl. CPC H01L 21/30625; H01L 21/3065; H01L 51/0023
USPC 438/46; 438/669

(57) ABSTRACT

A method for manufacturing a semiconductor device may include: forming a metal layer structure over a semiconductor workpiece; forming a first layer over the metal layer structure, the first layer including a first material; forming at least one opening in the first layer and the metal layer structure; depositing a second layer to fill the at least one opening and at least partially cover a surface of the first layer facing away from the metal layer structure, the second layer including a second material that is different from the first material; removing the second layer from at least the surface of the first layer facing away from the metal layer structure; and removing the first layer.

### TECHNICAL FIELD

Various embodiments relate to a method for manufacturing a semiconductor device.

### BACKGROUND

Semiconductor devices may include metal layers. For example, metal layers may be used as electrodes, e.g. anodes, in optical devices such as, e.g., organic light emitting devices, e.g. organic light emitting diodes (OLEDs). In this context, it may be desirable to produce large flat metal layers of high quality, e.g. having low surface roughness.

### SUMMARY

A method for manufacturing a semiconductor device in accordance with various embodiments may include: forming a metal layer structure over a workpiece; forming a first layer over the metal layer structure, the first layer including a first material; forming at least one opening in the first layer and the metal layer structure; depositing a second layer to fill the at least one opening and at least partially cover a surface of the first layer facing away from the metal layer structure, the second layer including a second material that is different from the first material; removing the second layer from at least the surface of the first layer facing away from the metal layer structure; and removing the first layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 illustrates a method for manufacturing a semiconductor device in accordance with various embodiments;

FIG. 2 illustrates a method for manufacturing a semiconductor device in accordance with various embodiments;

FIG. 3 illustrates a method for manufacturing a semiconductor device in accordance with various embodiments;

FIGS. 4A to 4G illustrate a method for manufacturing a semiconductor device in accordance with various embodiments.

### DESCRIPTION

The following detailed description refers to the accompanying drawings that show, by way of illustration, specific details and embodiments in which the invention may be practised. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments. Various embodiments are described in connection with methods and various embodiments are described in connection with devices. However, it may be understood that embodiments described in connection with methods may similarly apply to the devices, and vice versa.

Any embodiment or design described herein is not necessarily to be construed as preferred or advantageous over other embodiments or designs.

The terms “at least one” and “one or more” may be understood to include any integer number greater than or equal to one, i.e. one, two, three, four, etc.

The term “a plurality” may be understood to include any integer number greater than or equal to two, i.e. two, three, four, five, etc.

The word “over”, used herein to describe forming a feature, e.g. a layer, “over” a side, a surface, or another feature (e.g. another layer), may be used to mean that the feature, e.g. the layer, may be formed “directly on”, e.g. in direct contact with, the implied side, surface or other feature (e.g., other layer). The word “over”, used herein to describe forming a feature, e.g. a layer, “over” a side, a surface, or another feature (e.g. another layer), may be used to mean that the feature, e.g. the layer, may be formed “indirectly on” the implied side, surface or other feature (e.g., other layer) with one or more additional layers being arranged between the implied side, surface, or other feature (e.g., other layer), and the formed layer.

Directional terminology, such as e.g. “upper”, “lower”, “top”, “bottom”, “left-hand”, “right-hand”, etc., may be used with reference to the orientation of figure(s) being described. Because components of the figure(s) may be positioned in a number of different orientations, the directional terminology is used for purposes of illustration and is in no way limiting. It is to be understood that structural or logical changes may be made without departing from the scope of the invention.

In one or more embodiments, layers described herein may be formed by means of deposition processes, e.g. any suitable deposition processes applied in semiconductor processing technologies, including e.g. chemical vapor deposition (CVD), physical vapor deposition (PVD), electroless plating, electroplating, spin coating, spray coating, and the like. Deposition processes as such are well known in the art and will not be described in detail here.

In accordance with various embodiments described herein, a sacrificial or etch stop layer (e.g., a carbon layer) may be used to protect a metal layer structure (e.g., a metal layer or metal layer stack, e.g. a top liner of a metal layer stack) from aggressive processes such as, e.g., CMP (chemical mechanical polishing) or plasma etch processes used to remove any topology created during filling of openings or gaps with, e.g., dielectric material. Thus, a surface of the metal layer structure may remain undamaged, such that, e.g., an initial optical condition (e.g. low surface roughness and/or high reflectivity) of the metal layer structure may be preserved.

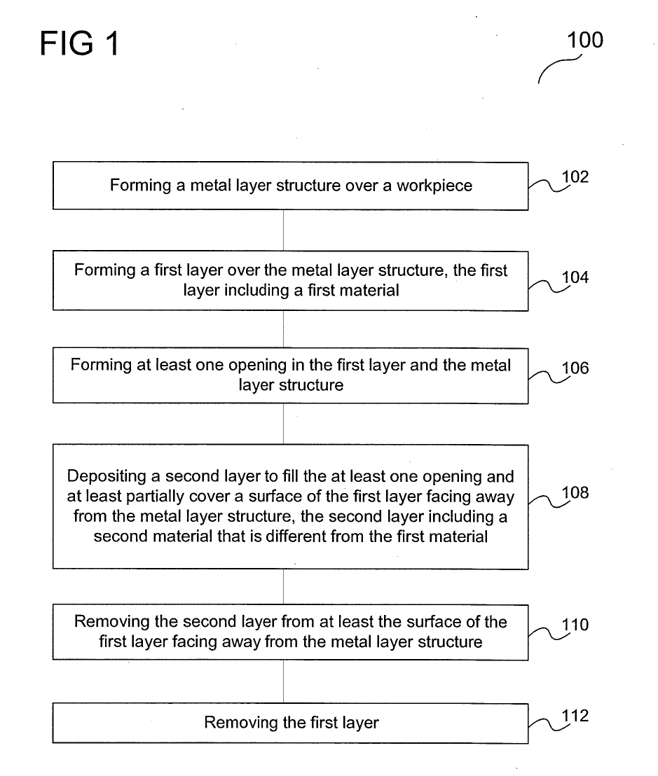

FIG. 1 illustrates a method 100 for manufacturing a semiconductor device in accordance with various embodiments.

Method 100 includes: forming a metal layer structure over a workpiece (in 102); forming a first layer over the metal layer structure, the first layer including a first material (in 104); forming at least one opening in the first layer and the metal layer structure (in 106); depositing a second layer to fill the at least one opening and at least partially cover a surface of the first layer facing away from the metal layer structure, the second layer including a second material that is different from the first material (in 108); removing the second layer from at least the surface of the first layer facing away from the metal layer structure (in 110); and removing the first layer (in 112).

In one or more embodiments, the surface of the first layer facing away from the metal layer structure may be an upper surface of the first layer.

In one or more embodiments, the first layer may consist of the first material.

In one or more embodiments, the first material may include, or may be, carbon.

In one or more embodiments, the first layer may be a carbon layer.

In one or more embodiments, forming the carbon layer may include, or may be effected by, a chemical vapor deposition (CVD) process, for example a plasma enhanced chemical vapor deposition (PECVD) process. Other deposition techniques or processes such as, for example, a physical vapor deposition (PVD) or a spin coating process, may be used as well. In one or more embodiments, a deposition temperature may be less than or equal to about 450° C. In one or more embodiments, the carbon layer may be an amorphous hydrogen containing carbon layer (n-C:H layer). In other words, carbon in the carbon layer may be present in an a-C:H configuration. An a-C:H layer may have isotropic film properties which may be beneficial for the use as an etch hardmask and/or as a CMP stopping layer. According to other embodiments, the carbon in the carbon layer may be present in other configurations.

In one or more embodiments, the first material may include, or may be, a dielectric material.

In one or more embodiments, the first material may include, or may be, a nitride material, e.g. a silicon nitride material, e.g. SiₓN_{y}, e.g. Si₃N₄.

In one or more embodiments, the second layer may consist of the second material.

In one or more embodiments, the second material may include, or may be, a material that may be selectively etched with respect to the first material.

In one or more embodiments, an etch rate ratio between the second material and the first material (in other words, a ratio r2:r1 between an etch rate, r2, of the second material and an etch rate, r1, of the first material) may be greater than or equal to 5, e.g. greater than or equal to 10.

In one or more embodiments, the second material may include, or may be, a dielectric material.

In one or more embodiments, the second material may include, or may be, an oxide material, e.g. a silicon oxide material, e.g. SiₓO_{y}, e.g. SiO₂.

In one or more embodiments, depositing the second layer may include, or may be effected by means of, depositing a tetraethyl orthosilicate (TEOS) layer. In other embodiments, depositing the second layer may include, or may be effected by means of, other suitable deposition processes.

In one or more embodiments, the first layer may be configured as, or may serve as, a sacrificial layer.

In one or more embodiments, the first layer may be configured as, or may serve as, an etch stop layer.

In one or more embodiments, the second layer may be configured as, or may serve as, a filling layer.

In one or more embodiments, removing the second layer from at least the surface of the first layer facing away from the metal layer structure may include, or may be effected by, applying a chemical mechanical polishing (CMP) process.

In one or more embodiments, the first layer may be configured as, or may serve as, a stopping layer for the CMP process.

In one or more embodiments, removing the second layer from at least the surface of the first layer facing away from the metal layer structure may include, or may be effected by, applying an etch process, for example an etch process without a mechanical polishing component.

In one or more embodiments, the etch process may be a plasma etch process.

In one or more embodiments, the first layer may be configured as, or may serve as, an etch stop layer for the etch process.

In one or more embodiments, removing the first layer may include, or may be effected by, applying an ashing process.

In one or more embodiments, removing the first layer may include, or may be effected by, applying an etch process.

In one or more embodiments, the etch process may be a wet etch process.

In one or more embodiments, the first material may include, or may be, carbon, and removing the first layer may include, or may be effected by, applying an ashing process.

In one or more embodiments, the first material may include, or may be, a dielectric material (e.g. a nitride material), and removing the first layer may include, or may be effected by, applying an etch process.

In one or more embodiments, forming the at least one opening may include applying a photolithographic patterning process.

In one or more embodiments, the photolithographic patterning process may include forming at least one mask layer over the first layer and patterning the at least one mask layer to form a patterned mask.

In one or more embodiments, the at least one mask layer may include a photoresist layer.

In one or more embodiments, the at least one mask layer may include a hard mask layer.

In one or more embodiments, the hard mask layer may include, or may be made of, at least one of an oxide material (e.g. a silicon oxide material), a nitride material (e.g. a silicon nitride material), and an oxynitride material (e.g. a silicon oxynitride material).

In one or more embodiments, forming the at least one opening may further include etching the first layer and the metal layer structure using the patterned mask.

In one or more embodiments, the at least one opening may include or may be at least one trench.

In one or more embodiments, the at least one opening may have a width or diameter in the range from about 500 nm to about 500 μm, e.g. a width or diameter of about 1 μm, although other values of the width or diameter may be possible as well.

In one or more embodiments, the workpiece may be a semiconductor workpiece.

In one or more embodiments, the workpiece may include, or may be, a semiconductor wafer.

In one or more embodiments, the semiconductor wafer may be a silicon wafer.

In one or more embodiments, the semiconductor wafer may include a dielectric layer disposed at a surface of the semiconductor wafer.

In one or more embodiments, the semiconductor wafer may further include a semiconductor body, and the dielectric layer may be disposed over the semiconductor body.

In one or more embodiments, forming the metal layer structure over the workpiece may include forming the metal layer structure over the dielectric layer of the semiconductor wafer.

In one or more embodiments, the dielectric layer of the semiconductor wafer may include, or may be made of, the second material.

In one or more embodiments, the dielectric layer may be an oxide layer, e.g. a silicon oxide layer.

In one or more embodiments, the metal layer structure may include, or may be made of, at least one of aluminum (Al), copper (Cu), and an alloy containing at least one of aluminum and copper.

In one or more embodiments, the metal layer structure may include, or may be made of, an Al—Cu alloy, e.g. an Al—Cu alloy containing about 5 wt. % Cu.

In one or more embodiments, the metal layer structure may include, or may be, a single layer, e.g. a single layer including, or being made of, at least one of Al, Cu, and an alloy containing at least one of Al and Cu.

In one or more embodiments, the metal layer structure may include, or may be, a layer stack including a plurality of sublayers. The sublayers may be stacked on top of each other.

In one or more embodiments, the plurality of sublayers may include, or may consist of, a first sublayer including or being made of a first metallic material, a second sublayer disposed over the first sublayer and including or being made of a second metallic material, and a third sublayer disposed over the second sublayer and including or being made of a third metallic material.

In one or more embodiments at least one of the first and third sublayers may be configured as, or may serve as, a liner.

In one or more embodiments, at least one of the first and third metallic materials may be selected from a group of materials, the group consisting of: Ti, TiN.

In one or more embodiments, the first metallic material and the third metallic material may be the same material.

In one or more embodiments, the first metallic material and the third metallic material may be different materials.

In one or more embodiments, the second metallic material may be selected from a group of materials, the group consisting of: aluminum (Al), copper (Cu), tantalum (Ta), TaN, an alloy including at least one of aluminum and copper, for example AlTi, AlSiTi.

In one or more embodiments, the second metallic material may include, or may be, an Al—Cu alloy, e.g. an Al—Cu alloy containing about 5 wt. % Cu.

In one or more embodiments, the first metallic material may be TiN, the second metallic material may be an alloy including Al and Cu, and the third metallic material may be TiN.

In one or more embodiments, the metal layer structure may have a thickness in the range from about 40 nm to about 350 nm, e.g. about 100 nm, or less than or equal to about 70 nm.

In one or more embodiments, the first sublayer of the layer stack may have a thickness in the range from about 5 nm to about 25 nm, e.g. about 10 nm.

In one or more embodiments, the second sublayer of the layer stack may have a thickness in the range from about 30 nm to about 300 nm, for example about 50 nm.

In one or more embodiments, the third sublayer of the layer stack may have a thickness in the range from about 5 nm to about 25 nm, for example about 10 nm.

In one or more embodiments, the first layer may have a thickness of greater than or equal to about 40 nm, for example in the range from about 20 nm to about 60 nm, e.g. about 40 nm.

In one or more embodiments, the second layer (for example, a portion of the second layer covering the surface of the first layer facing away from the workpiece) may have a thickness in the range from about 170 nm to about 550 nm, for example about 250 nm.

In one or more embodiments, method 100 may further include forming at least one organic semiconducting layer over the metal layer structure after removing the first layer.

In one or more embodiments, the at least one organic semiconducting layer may include or may be an organic light emitting layer.

In one or more embodiments, method 100 may further include configuring the semiconductor device as at least one organic light emitting diode (OLED).

In one or more embodiments, method 100 may further include configuring the metal layer structure as at least one electrode of the at least one organic light emitting diode.

In one or more embodiments, method 100 may further include configuring the metal layer structure as at least one anode of the at least one organic light emitting diode.

In one or more embodiments, method 100 may further include removing the second layer from at least a portion of at least one sidewall of the first layer before removing the first layer. For example, the second layer may be removed from the at least one sidewall of the first layer before removing the first layer. In one or more embodiments, removing the second layer from at least a portion of at least one sidewall may include, or may be effected by, applying an etch process.

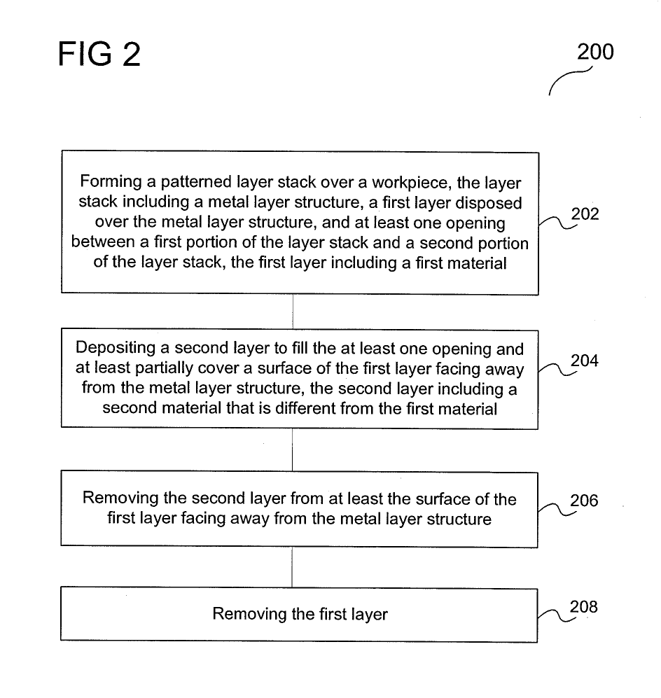

FIG. 2 illustrates a method 200 for manufacturing a semiconductor device in accordance with various embodiments.

Method 200 includes: forming a patterned layer stack over a workpiece, the layer stack including a metal layer structure, a first layer disposed over the metal layer structure, and at least one opening between a first portion of the layer stack and a second portion of the layer stack, the first layer including a first material (in 202); depositing a second layer to fill the at least one opening and at least partially cover a surface of the first layer facing away from the metal layer structure, the second layer including a second material that is different from the first material (in 204); removing the second layer from at least the surface of the first layer facing away from the metal layer structure (in 206); and removing the first layer (in 208).

In one or more embodiments, the workpiece may include a dielectric layer, and the patterned layer stack may be formed over the dielectric layer.

In one or more embodiments, the first material may include, or may be, carbon.

In one or more embodiments, the second material may include, or may be, a dielectric material.

Method 200 may further be configured in accordance with one or more embodiments described herein.

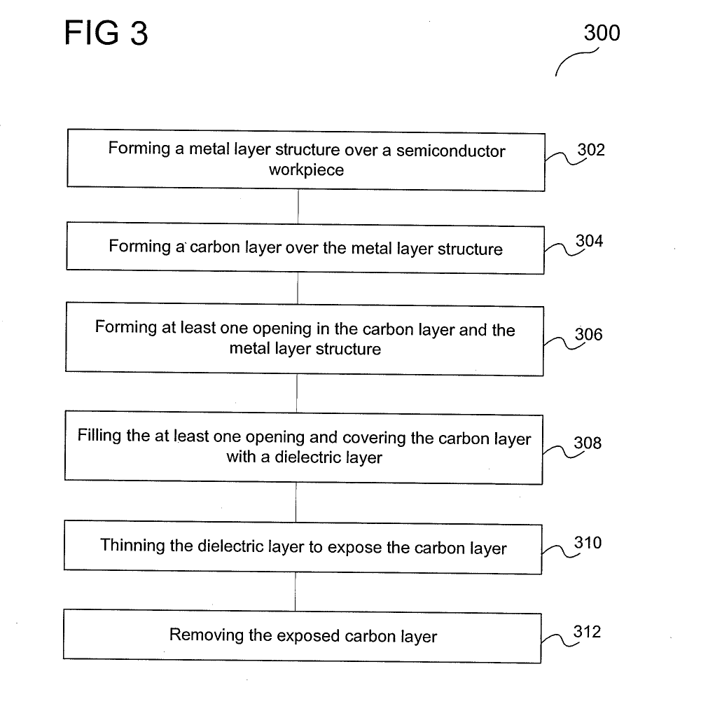

FIG. 3 illustrates a method 300 for manufacturing a semiconductor device in accordance with various embodiments.

Method 300 includes: forming a metal layer structure over a semiconductor workpiece (in 302); forming a carbon layer over the metal layer structure (in 304); forming at least one opening in the carbon layer and the metal layer structure (in 306); filling the at least one opening and covering the carbon layer with a dielectric layer (in 308); thinning the dielectric layer to expose the carbon layer (in 310); and removing the exposed carbon layer (in 312).

In one or more embodiments, thinning the dielectric layer may include, or may be effected by, applying at least one of a chemical mechanical polishing (CMP) process and a plasma etch process.

In one or more embodiments, removing the carbon layer may include, or may be effected by, applying an ashing process.

Method 300 may further be configured in accordance with one or more embodiments described herein.

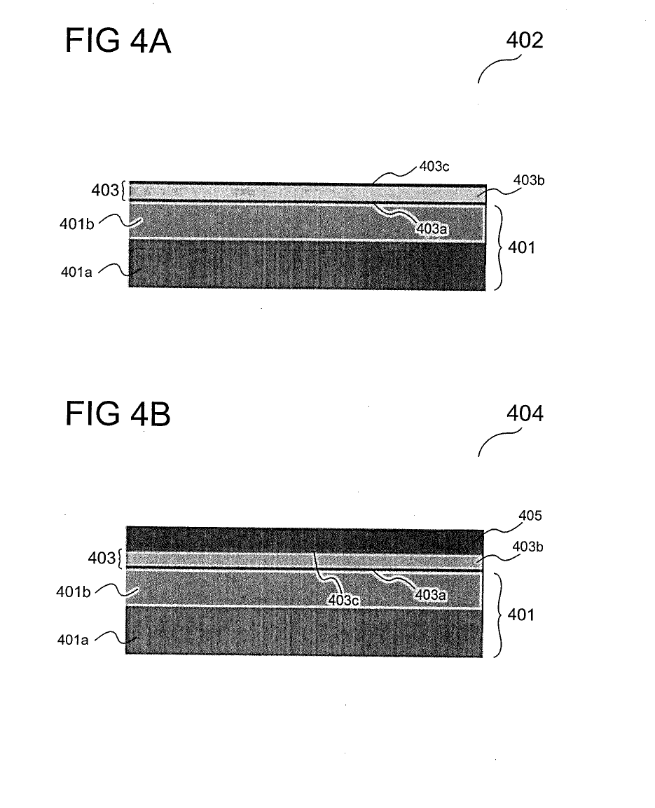

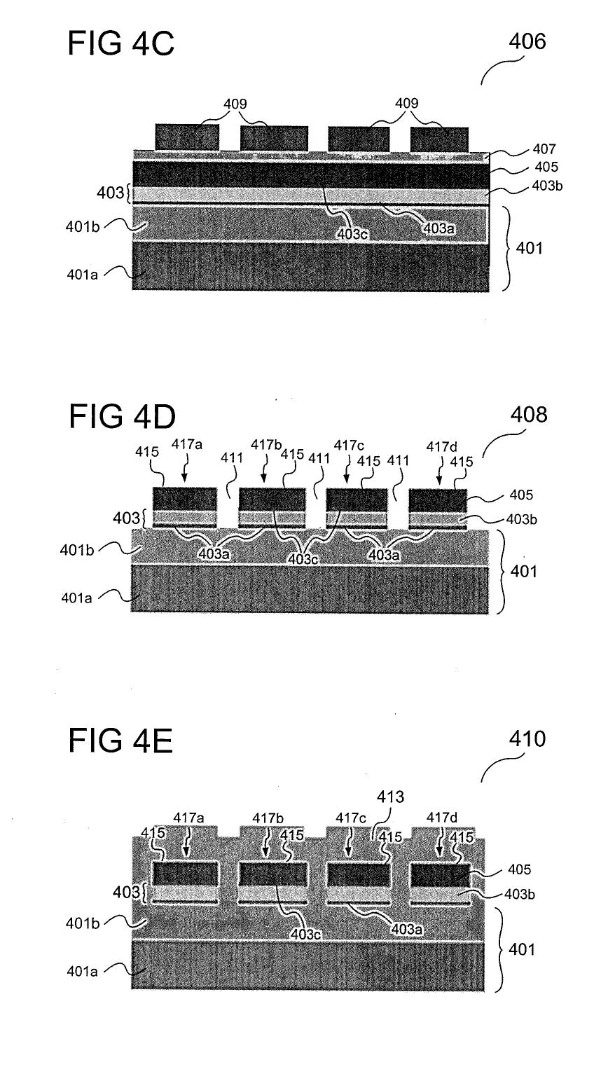

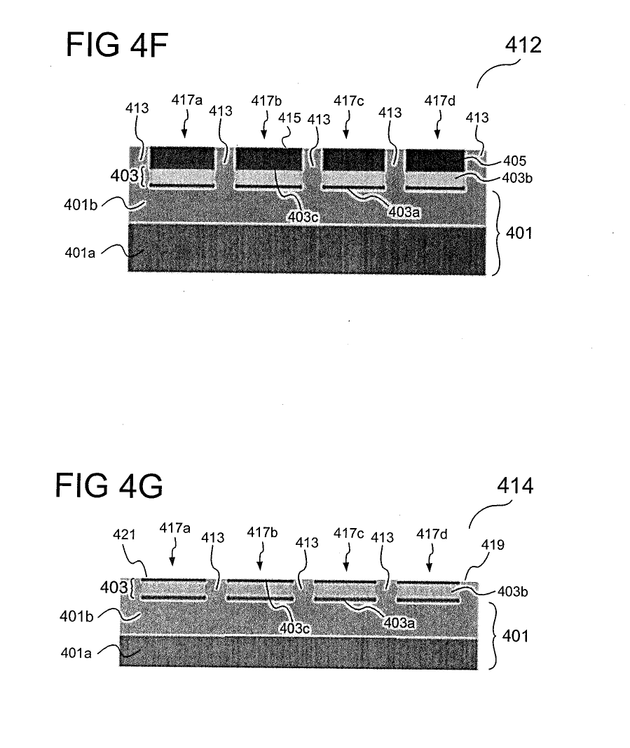

FIGS. 4A to 4G illustrate a method for manufacturing a semiconductor device in accordance with various embodiments.

FIG. 4A shows, in a cross-sectional view 402, that a metal layer structure 403 may be formed (e.g. deposited) over a workpiece 401.

In one or more embodiments, the workpiece 401 may include a semiconductor wafer 401a including a dielectric layer 401b disposed at a surface of the wafer 401a, as shown. In one or more embodiments, the semiconductor wafer 401a may be a silicon wafer. In one or more embodiments, the semiconductor wafer 401a may include one or more electric and/or electronic elements, e.g. one or more circuits including one or more electric or electronic elements such as, e.g., one or more interconnects, resistors, diodes, transistors, or the like. In one or more embodiments, the dielectric layer 401b may be an oxide layer. In one or more embodiments, the dielectric layer 401b may be a silicon oxide layer. In one or more embodiments, the dielectric layer, e.g. oxide layer, 401b may have been formed by a chemical vapor deposition (CVD) process, e.g. a plasma-enhanced CVD process, e.g. using a high-density plasma. In one or more embodiments, the dielectric layer 401b may have a thickness in the range from about 100 nm to about 1000 nm, for example about 500 nm in one embodiment. The thickness of the dielectric layer 401b may, for example, depend on the type of interface between the metal layer structure 403 and the semiconductor wafer 401 below. In one or more embodiments, the dielectric layer 401b may be omitted.

Alternatively or in addition, the workpiece 401 may be configured in accordance with one or more embodiments described herein.

In one or more embodiments, the metal layer structure 403 may include a layer stack including a plurality of sublayers, for example a first sublayer 403a including a first metallic material, a second sublayer 403b disposed over the first sublayer 403a and including a second metallic material, and a third sublayer 403c disposed over the second sublayer 403b and including a third metallic material, as shown. In one or more embodiments, the first sublayer 403a may be configured as a first liner (e.g. lower liner). For example, the first metallic material may be a liner material such as, e.g., TiN or the like. In one or more embodiments, the second metallic material (of the second sublayer 403b) may be aluminum, or copper, or an alloy containing aluminum and copper, e.g. AlCu with 5% Cu. In one or more embodiments, the third sublayer 403c may be configured as a second liner (e.g. upper liner). For example, the third metallic material may be a liner material such as, e.g., TiN or the like.

Alternatively or in addition, the metal layer structure 403 may be formed and/or configured in accordance with one or more embodiments described herein. For example, in one or more embodiments, the metal layer structure 403 may include or consist of less than three sublayers, e.g. a single layer or two sublayers, or may include or consist of more than three sublayers.

FIG. 4B shows, in a cross-sectional view 404, that a first layer 405 may be formed (e.g. deposited) over the metal layer structure 403, for example over the third sublayer 403c of the layer stack, as shown. The first layer 405 may include or may be made of a first material. In one or more embodiments, the first material may be carbon. For example, the first layer 405 may be a carbon layer. In other embodiments, the first material may be a dielectric material such as, e.g., a nitride. In one or more embodiments, the first layer 405 (e.g. carbon layer) may have a thickness of greater than or equal to about 40 nm. The first layer 405 may subsequently serve as a sacrificial layer or etch stop layer to protect the metal layer structure 403.

Alternatively or in addition, the first layer 405 may be formed and/or configured in accordance with one or more embodiments described herein.

Referring to FIGS. 4C and 4D, the first layer 405 and the metal layer structure 403 may be patterned, thereby forming at least one opening 411 in the first layer 405 and the metal layer structure 403.

FIG. 4C shows, in a cross-sectional view 406, that a hard mask layer 407 may be formed (e.g. deposited) over the first layer 405. In one or more embodiments, the hard mask layer 407 may include or may be made of a hard mask material. In one or more embodiments, the hard mask material may be an oxynitride material. In one or more embodiments, the hardmask material may be a silicon oxynitride material. As is shown in FIG. 4C, a photoresist layer 409 may be formed (e.g. deposited) over the hard mask layer 407 in one or more embodiments. The photoresist layer 409 may be patterned by means of a standard photolithographic process, including using a photomask to expose the photoresist layer 409 and subsequently developing the exposed photoresist layer 409 to uncover one or more portions of the hard mask layer 407, as shown in FIG. 4C.

The patterned photoresist layer 409 may then be used to pattern the hard mask layer 407, e.g. by means of an etch process using the patterned photoresist layer 409 as a mask. The patterned hard mask layer 407 may then be used to pattern the first layer 405 (e.g. carbon layer), e.g. by means of an etch process using the patterned hard mask layer 407 as a mask. In the course of etching the first layer 405 (e.g. carbon layer), the patterned photoresist layer 409 may be at least partially removed from above the patterned hard mask layer 407. For example, in one or more embodiments, the patterned photoresist layer 409 may be completely removed by the etch process.

The patterned hard mask layer 407 and patterned first layer 405 (e.g. carbon layer) may then be used to pattern the metal layer structure 403, e.g. by means of an etch process using the patterned hard mask layer 407 and the patterned first layer 405 as a mask. In the course of etching the metal layer structure 403, the patterned hard mask layer 407 may be at least partially removed from above the patterned first layer 405 (e.g. carbon layer). For example, in one or more embodiments, the patterned hard mask layer 407 may be completely removed by the etch process, as is shown in FIG. 4D. In one or more embodiments, etching the metal layer structure 403 may thin the first layer 405 to some degree. In one or more embodiments, the first layer 405 may have a thickness of greater than or equal to about 20 nm after etching the metal layer structure 403, for example in the range from about 20 nm to about 40 nm, e.g. about 40 nm, although the thickness may have other values as well, e.g. less than 20 nm or greater than 40 nm.

FIG. 4D shows, in a cross-sectional view 408, that at least one opening 411, e.g. a plurality of openings 411 in accordance with one more embodiments, as shown, are formed in the first layer 405 and the metal layer structure 403 below. In one or more embodiments, the at least one opening 411 may include or may be at least one trench. The opening or openings 411 may separate or insulate one or more portions of the layer stack including the metal layer structure 403 and the first layer 405. In particular, the opening or openings 411 may electrically insulate one or more portions of the metal layer structure 403. For example, four separate or insulated portions 417a, 417b, 417c, 417d are shown as an example in FIG. 4D, however the number of separate or insulated portions may be different from four, and may, e.g., be on the order of tens, hundreds, or even more. Each portion of the metal layer structure 403 may, for example, later be configured as an electrode, e.g. an anode, e.g. of an organic light emitting device, e.g. an OLED, in accordance with one or more embodiments, although other applications may be possible as well.

FIG. 4E shows, in a cross-sectional view 410, that a second layer 413 may be deposited to fill the at least one opening 411 and at least partially cover a surface 415 of the first layer 405 facing away from the metal layer structure 403. The second layer 413 may include or may be made of a second material that is different from the first material.

In one or more embodiments, the second layer 413 may fill the space or spaces between the one or more portions 417a, 417b, 417c, 417d of the layer stack, for example between the patterned metal layer structure 403 and the patterned first layer (e.g. carbon layer) 405, and may cover a top surface (e.g. surface 415) of the patterned first layer 405.

In one or more embodiments, the second material may include, or may be, a material that may be selectively etched with respect to the first material (of the first layer 405).

In one or more embodiments, an etch rate ratio between the second material (of the second layer 413) and the first material (of the first layer 405) may be as described herein above in connection with FIG. 1.

In one or more embodiments, the second material may include, or may be, a dielectric material.

In one or more embodiments, the second material may include, or may be, the same material as the dielectric layer 401b of the wafer 401.

In one or more embodiments, the second material may include, or may be, an oxide material, e.g. a silicon oxide material, e.g. SiₓO_{y}, e.g. SiO₂.

In one or more embodiments, depositing the second layer 413 may include, or may be effected by means of, depositing a tetraethyl orthosilicate (TEOS) layer. In other embodiments, depositing the second layer 413 may include, or may be effected by means of, other suitable deposition processes.

FIG. 4F shows, in a cross-sectional view 412, that the second layer 413 may be removed from at least the surface 415 of the first layer 405 facing away from the metal layer structure 403.

Thus, the surface 415 (e.g. top surface) of the first layer 405 may be exposed.

In one or more embodiments, removing the second layer 413 may include, or may be effected by, applying a chemical mechanical polishing (CMP) process.

In one or more embodiments, the first layer 405 may be configured as, or may serve as, a stopping layer for the CMP process. In other words, the CMP process may stop at the first layer 405, for example at the surface 415 (e.g. top surface) of the first layer 405.

In one or more embodiments, removing the second layer 413 may include, or may be effected by, applying an etch process.

In one or more embodiments, the etch process may include or may be a plasma etch process.

In one or more embodiments, the first layer 405 may be configured as, or may serve as, an etch stop layer for the etch process. In other words, the etch process may stop at the first layer 405, for example at the surface 415 (e.g. top surface) of the first layer 405.

In one or more embodiments, the second layer 413 may be removed, e.g. etched, to a level below the surface 415 (e.g. top surface) of the first layer 405, for example to a level of an interface between the first layer 405 and the metallization layer structure 403, for example to a level of an interface between the first layer 405 and the third sublayer (e.g. upper liner) 403c of the metallization layer structure 403. That is, in one or more embodiments, a portion of the second layer 413 filling the at least one opening 411, e.g. a portion of the second layer 413 between the one or more portions 417a, 417b, 417c, 417d, e.g. a portion of the second layer 413 disposed over a sidewall or sidewalls of the first layer 405, may be removed, for example by means of the aforementioned etch process or by means of a separate etch process.

FIG. 4G shows, in a cross-sectional view 414, that the first layer 405 may be removed.

In one or more embodiments, removing the first layer 405 may include, or may be effected by, applying an ashing process. For example, in one or more embodiments, a first layer 405 including carbon or made of carbon may be removed by ashing.

In one or more embodiments, removing the first layer 405 may include, or may be effected by, applying an etch process. For example, in one or more embodiments, a first layer 405 including a nitride material or made of a nitride material (e.g. a silicon nitride material) may be removed by means of an etch process. In one or more embodiments, the etch process may be a wet etch process.

By removing the first layer 405, the underlying metal layer structure 403, e.g. a top surface of the metal layer structure 403, e.g. a top surface of the third sublayer 403c, may be exposed.

As shown, a semiconductor device may be obtained that may include one or more portions 417a, 417b, 417c, 417d of the metal layer structure 403 insulated by the second layer 413.

In one or more embodiments, a surface 419 of the second layer 413 facing away from the workpiece 401 (e.g. a top surface of the second layer 413) may be substantially flush with a surface 421 of the metal layer structure 403 facing away from the workpiece 401 (e.g. a top surface of the metal layer structure 403), as shown. In other embodiments, the surface 419 of the second layer 413 may be at a different level than the surface 421 of the metal layer structure 403. For example, the surface 419 may be at a higher level than the surface 421. In other words, the surface 419 may be disposed farther away from the workpiece 401 than the surface 421. In still other words, the second layer 413 may protrude beyond the metal layer structure 403. In still other words, the second layer 413 may constitute a step with positive step height relative to the metal layer structure 403. For example, in one or more embodiments, the step height may be on the order of a few nanometers, or a few tens of a nanometer, e.g. in the range from about 5 nm to about 30 nm, e.g. about 10 nm, although other values of the step height may be possible as well.

In one or more embodiments, the semiconductor device shown in FIG. 4G may be subjected to further processing. For example, in one or more embodiments, the one or more portions 417a, 417b, 417c, 417d of the metal layer structure 403 may be configured as one or more electrodes, e.g. anodes, of an organic light emitting device, e.g. an OLED device, and one or more organic light emitting layers may be formed (e.g. deposited) over the one or more electrodes. In other embodiments, the semiconductor device may be configured differently, for example as a sensor, or as other type of device.

In the following, various aspects and potential effects of one or more embodiments will be described.

One or more embodiments described herein may be applied, for example, in the fabrication of organic light emitting devices, e.g. OLED devices, on CMOS (complementary metal oxide semiconductor). In accordance with one or more embodiments, an integration scheme is provided enabling, e.g., fabrication of a thin, metallic, highly-reflective anode layer where spaces between individual anodes may be filled and planarized without damaging the sensitive anode.

One or more embodiments may prevent, or at least substantially reduce the likelihood, that an optical sensitive metal layer will be damaged by a CMP or plasma etch process.

Conventionally, a gap between metal plates may be filled with a dielectric (e.g. oxide) and then planarized by a CMP process stopping on the optical sensitive layer itself, or by etching away the dielectric using a plasma etch process. However, this may have the effect that the CMP stopping layer cannot be used as an optical layer anymore because it may have been scratched by the CMP down force or may have been damaged by the plasma used in the plasma etch process. In particular, uniformity and/or optical properties of the metal plate may deteriorate due to the CMP or plasma etch process.

In accordance with one or more embodiments, a sacrificial or etch stop layer (e.g., a carbon layer) may be provided on top of the metal layer or metal layer stack after the metal plate patterning and during the filling of the gaps with dielectric. The sacrificial or etch stop layer (e.g., carbon layer) may be used as a stopping layer for the CMP process (e.g. oxide CMP process). After the planarization, the sacrificial or etch stop layer (e.g. carbon layer) may be removed easily, e.g. by means of ashing, e.g., with a downstream stripper tool, and the metal layer or metal layer stack (e.g., a top liner of the metal layer stack) may be still undamaged because it was protected by the sacrificial or etch stop layer (e.g., carbon layer) that acts as a sacrificial layer, which is used just as CMP stopping layer and then stripped away.

One or more embodiments described herein may be applied to create large flat metal plates with high reflectivity, no spikes and low roughness separated by dielectric material. This may enable an overall flat conductive surface that may, e.g., be used for an OLED deposition to build, e.g., micro displays.

A method for manufacturing an organic light emitting device in accordance with various embodiments may include: forming a metal layer structure over a semiconductor workpiece; forming a first layer over the metal layer structure, the first layer comprising a first material; forming at least one opening in the first layer and the metal layer structure; depositing a second layer to fill the at least one opening and at least partially cover a surface of the first layer facing away from the metal layer structure, the second layer comprising a second material that is different from the first material, wherein the second material is a dielectric material; removing the second layer from at least the surface of the first layer facing away from the metal layer structure; removing the first layer to expose the metal layer structure; and forming at least one organic light emitting layer over the exposed metal layer structure.

In one or more embodiments, the first material may include or may be carbon.

The method may further be configured in accordance with one or more embodiments described herein.

While various aspects of this disclosure have been particularly shown and described with reference to specific embodiments, it should be understood by those skilled in the art that various changes in form and detail may be made therein without departing from the spirit and scope of the disclosure as defined by the appended claims. The scope of the disclosure is thus indicated by the appended claims and all changes which come within the meaning and range of equivalency of the claims are therefore intended to be embraced.

What is claimed is:

1. A method for manufacturing a semiconductor device, the method comprising:
forming a metal layer structure over a workpiece;
forming a first layer over the metal layer structure, the first layer comprising a first material;
forming at least one opening in the first layer and the metal layer structure;
depositing a second layer to fill the at least one opening and at least partially cover a surface of the first layer facing away from the metal layer structure, the second layer comprising a second material that is different from the first material;
removing the second layer from at least the surface of the first layer facing away from the metal layer structure; and
removing the first layer.

2. The method of claim 1, wherein the first material comprises carbon.

3. The method of claim 1, wherein the first material comprises a dielectric material.

4. The method of claim 1, wherein the second material comprises a dielectric material.

5. The method of claim 1, wherein removing the second layer from at least the surface of the first layer facing away from the metal layer structure comprises applying a chemical mechanical polishing (CMP) process.

6. The method of claim 1, wherein removing the second layer from at least the surface of the first layer facing away from the metal layer structure comprises applying an etch process.

7. The method of claim 6, wherein the etch process is a plasma etch process.

8. The method of claim 1, wherein removing the first layer comprises applying an ashing process.

9. The method of claim 1, wherein removing the first layer comprises applying an etch process.

10. The method of claim 1, wherein forming the at least one opening comprises applying a photolithographic patterning process.

11. The method of claim 21, wherein the photolithographic patterning process comprises forming at least one mask layer over the first layer and patterning the at least one mask layer to form a patterned mask.

12. The method of claim 11, wherein forming the at least one opening further comprises etching the first layer and the metal layer structure using the patterned mask.

13. The method of claim 1, wherein forming the metal layer structure over the workpiece comprises forming the metal layer structure over a dielectric layer of the workpiece.

14. The method of claim 13, wherein the second material and a material of the dielectric layer are the same material.

15. The method of claim 1, wherein the metal layer structure comprises at least one of aluminum and copper.

16. The method of claim 1, wherein the metal layer structure comprises a layer stack comprising a plurality of sublayers.

17. The method of claim 16, wherein the plurality of layers comprises a first sublayer comprising a first metallic material, a second sublayer disposed over the first sublayer and comprising a second metallic material, and a third sublayer disposed over the second sublayer and comprising a third metallic material.

18. The method of claim 1, wherein the first layer has a thickness of greater than or equal to about 40 nm.

19. The method of claim 1, further comprising forming at least one organic semiconducting layer over the metal layer structure after removing the first layer.

20. The method of claim 19, wherein the at least one organic semiconducting layer comprises an organic light emitting layer.

21. The method of claim 1, further comprising removing the second layer from at least a portion of at least one sidewall of the first layer before removing the first layer.

22. A method for manufacturing a semiconductor device, the method comprising:
forming a patterned layer stack over a workpiece, the layer stack comprising a metal layer structure, a first layer disposed over the metal layer structure, and at least one opening between a first portion of the layer stack and a second portion of the layer stack, the first layer comprising a first material;
depositing a second layer to fill the at least one opening and at least partially cover a surface of the first layer facing away from the metal layer structure, the second layer comprising a second material that is different from the first material, wherein the second material is a dielectric material;
removing the second layer from at least the surface of the first layer facing away from the metal layer structure; and
removing the first layer.

23. The method of claim 22, wherein the first material comprises carbon.

24. A method for manufacturing a semiconductor device, the method comprising:
forming a metal layer structure over a semiconductor workpiece;
forming a carbon layer over the metal layer structure;
forming at least one opening in the carbon layer and the metal layer structure;
filling the at least one opening and covering the carbon layer with a dielectric layer;
thinning the dielectric layer to expose the carbon layer; and
removing the exposed carbon layer.

25. The method of claim 24, wherein thinning the dielectric layer comprises applying at least one of a chemical mechanical polishing (CMP) process and a plasma etch process.
